(19) United States
(12) Patent Application Publication
(10) Pub. No.: US 2003/0178583 A1
(43) Pub. Date: Sep. 25, 2003

(54) Field emission photo-cathode array for lithography system and lithography system provided with such an array

(76) Inventors: Bert Jan Kampherbeek, Delft (NL); Marco Jan-Jaco Wieland, Delft (NL); Pieter Kruit, Delft (NL)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/392,228

(22) Filed: Mar. 18, 2003

Related U.S. Application Data
(63) Continuation-in-part of application No. PCT/NL00/00657, filed on Sep. 18, 2000.
(63) Continuation-in-part of application No. PCT/NL00/00658, filed on Sep. 18, 2000.

(51) Int. Cl. G21G 5/00; H01L 29/06; H01L 29/12; G21K 5/04; G03F 7/20

(52) U.S. Cl. 250/492.3; 257/10; 430/296

(57) ABSTRACT

The present invention relates to the use of an electron source in a lithography system for producing a plurality of electron beams directed towards an object to be processed, said electron source comprising a plurality of field emitters, characterized in that said electron source comprises a semiconductor layer with a plurality of tips, said use including the steps of:

producing a plurality of light spots on said electron source, producing one light spot on one field emitter;

exciting electrons to a conduction band (E_{c}) by light from a light spot within said field emitter by a photo-electric effect;

accelerating said electrons in said conduction band (E_{c}) towards said tips and tunnelling them outside tips in order to generate electrons for said plurality of electron beams,

causing tips to generate electrons for said electron beam having a spot smaller than 100 nm on an object to be processed, each spot of light triggering an electron beam from one tip.

### FIELD OF THE INVENTION

The invention relates to using an electron source for producing at least one electron beam directed towards and focused on an object to be processed, the electron source comprising at least one field emitter.

The invention also relates to a lithography system provided with such a converter element.

### PRIOR ART

Converter elements for use in lithography systems, and designed to convert a light beam into a beam of charged particles are known from W098/54620. The purpose of these converter elements is to provide a better resolution (0.1 μm or less) in such systems than was possible with prior art systems without such converters in which the resolution was entirely determined by the wavelength of the light beam used.

First of all a description of such a system as described in W098/54620 is given.

To that end, reference is made to FIG. 1.

The background of the system described in W098/54620 is as follows.

Imagine that there is provided a known deep-UV lithography tool (i. e., wavelength 193 nm or less) for the 0.13 μm generation with a“traditional”4× mask for obtaining the 0.1 μm generation. Then, at a wafer surface, each 0.4 μm “pixel” of a mask is focused to a spot of 0.13 μm. Since the distance between pixels at the wafer must be 0.1 μm, there is a mixing of information between neighboring pixels because the spots of 0.13 μm overlap each other. If we could sharpen up this 0.13 μm spot, this machine would be ready for the 0.1 generation. The sharpening up, or enhancement of resolution, cannot be done after the mixing of information has occurred.

According to one embodiment described in W098/54620 only one pixel of the mask is illuminated. Then there is only an isolated spot of 0.13 μm at an imaginary wafer plane. At the location of the spot in the imaginary wafer plane a converter element, for example in the form of a photocathode of size 0.1 μm, or a photocathode with a metallic aperture of diameter of 0.1 μm on top, is positioned. Such a photocathode provides an electron source that may have a diameter of 0.1 μm. The photocathode that is obtained in this way is imaged with magnification factor 1 onto the wafer in a real wafer plane spaced from the photocathode. This can be done either with acceleration inside a magnetic field or with a small accelerating electrostatic lens. The next step is to move the mask, e. g., 0.4 μm in order to illuminate an adjacent pixel on the mask while, at the same time, moving the wafer 0.4/4=0.1 μm in order to have the adjacent pixel on the wafer written. In such a way, the mask pattern is transferred to the wafer with the required resolution.

However, it would take a long time to write a whole wafer with this single beam.

However, the principle is the same when many pixels are written simultaneously.

Therefore, a multiple beamlet embodiment can also be used. In theory, the distance between separate beams at the wafer surface needs only to be as much as the point spread function. In practice, certainly when electrostatic focusing is used, the fabrication technology of the photocathode/lens array will determine the minimum distance.

The number of beams is estimated to be in the order of 10⁶-10⁸.

Such a multiple beamlet embodiment shown in FIG. 1. A light source (not shown) produces a light beam 13, preferably in deep UV. The light beam 13 impinges on a micro lens array 1 having lenses 2. The light beam 13 is as it were divided in beamlets 12, of which only one is shown for the sake of clarity. However, in practice there may as much as 10⁶-10⁸ beamlets 12. The lens 2 focuses the beamlet 12 on a mask 3 with spots of, e. g., 400 nm diameter. Each light beamlet 12 leaving the mask 3 passes a demagnifier 14, which is schematically indicated by lenses 4 and 5 and an aperture 6. However, other types of demagnifiers known from the prior art may be used instead. By the demagnifier 14 the beamlets 12 are focused on a converter plate 7 having converter elements 8 of which only one is indicated. If, as disclosed by W098/54620, the converter plate 7 is constituted by a photocathode having a plurality of apertures a plurality of electron beamlets 15 (only 1 being shown in FIG. 1) is generated. The electron beamlet 15 originates from the aperture and passes through focusing means, indicated schematically by a lens 9. Finally, the electron beamlet 15 impinges on the wafer 10 in wafer plane 11.

The mask 3 may be moved in the direction of arrow PI and the wafer in the direction of arrow P2. If the mask 3 is, e.g., moved 0.4 μm the wafer must be shifted 0.1 μm. Pixels could be arranged at random on the wafer 10. In an embodiment shown in FIG. 2, the wafer pixels are arranged in lines and columns and the scanning direction SCAN differs from the direction of the lines of pixels.

The resolution is enhanced by sharpening up pixel by pixel, using a photocathode with very many apertures. This known technology is called “Multiple Aperture Pixel by Pixel Enhancement of Resolution” or “MAPPER”-technology. It can be thought of as traditional projection lithography in which the mask information is split up and transferred to the wafer sequentially. It can also be thought of as multiple microcolumn lithography in which the electron sources are blanked by the mask.

W098/54620 suggests that the photocathode could be replaced by an array of field emitters. However, by that time it was thought that this could only be achieved by providing for each field emitter individual control by light switches on which the light beamlets impinge. This is a complex arrangement.

### SUMMARY OF THE INVENTION

It is an object of the invention to provide a field emitter photocathode array for a lithography system that can be produced relatively easily and can produce electron beams originating from a very small area.

To that end, the invention provides a use as defined at the outset, wherein the electron source comprises a semiconductor layer with at least one tip, and the use includes the steps of:

receiving light by the semiconductor layer

exciting electrons to a conduction band by the light within said semiconductor layer by a photoelectric effect

accelerating the electrons in the conduction band towards the at least one tip and tunneling them outside the at least one tip in order to generate electrons for said electron beam.

During their research carried out to find a suitable structure from a suitable material, the inventors found that they had to look for a material with the following properties:

the material should exhibit a field emission effect

the material should be able to convert light beamlets with a wavelength of, 400 nm or less, e. g., 193 nm, into charged particles with a relatively high conversion factor

the material should allow to manufacture a converter plate with a plurality of charged particle sources of very small size, i.e., for instance 100 nm or less, preferably 50 nm or less, in diameter, and far enough apart to prevent overlap of adjacent charged particle beams to prevent mixing of information

the charged particle sources should be capable of being switched on and off by switching on and off the light beamlets impinging upon the charged particle sources with a frequency of, e.g., 2 MHz or more

the charged particle sources should be very stable and capable of resisting relatively high pressures, e. g., pressures higher than 10⁻⁷ mbar.

It turned out that such a material of suitable structure had already been proposed for another field of technology, i. e., the field of image tubes, a long time ago. The inventors found that a semiconductor field emission array for image-tubes as disclosed by Schroder e. a. in the beginning of the seventies in “The semiconductor field-emission photocathode”, IEEE Transactions on Electron Devices, Vol. ED-21, No. 12, December 1974, could meet these requirements and, thus, advantageously be used in the recently developed MAPPER lithography concept, referred to above. Additionally it was found that especially for small wavelengths said conversion factor could be further improved by adding a fluorescent layer to the structure.

Moreover, it is a further object of the invention to provide a lithography system provided with such a field emitter photocathode array.

Therefore, the invention also relates to a lithography system comprising an electron source for receiving light and converting light in at least one electron beam directed towards and focused on an object to be processed, electron source comprising at least one field emitter, wherein the electron source comprises a semiconductor layer with at least one tip, and the lithography system being arranged to:

receive the light by said semiconductor layer

excite electrons to a conduction band by the light within the semiconductor layer by a photo-electric effect

accelerate the electrons in the conduction band towards at least one tip and tunnel them outside at least one tip in order to generate electrons for electron beam.

It is furthermore an object of the present invention to provide an field emitter photocathode array for a lithography system that has an enhanced yield.

To that end, the invention as defined is characterised in that the substrate layer is provided with a fluorescent layer to convert the light of a first wavelength into light with a second wavelength larger than the first wavelength.

The second wavelength is tuned to the converter layer such that photons having the second wavelength have a longer fre path length in th converter alyer than those having the first wavelength. Thereby, the efficiency of electron generation in the converter layer will be increased.

It is to be understood that “second wavelength” is not meant in a strict sense of there being prsent only one single second wavelength. The fluorescent layer will normally produce photons of different wavelengths, as known to presons skillen in the art.

Advantageous embodiments of the invention are defined in depending claims.

### BRIEF DESCRIPTION OF THE DRAWINGS

The invention will now be explained with reference to some drawings, which are only intended to illustrate the invention and not to limit its scope of protection.

FIG. 1 shows schematically a lithography system according to the prior art in which the field emitter photocathode array can be used;

FIG. 2 shows an example of a scanning direction of pixels on a wafer to be lithographed;

FIG. 3 shows a Scanning Electron Microscope image of a p-type silicon wafer with an array of tips;

FIG. 4 shows schematically the operation of a semiconductor field emission array as shown in FIG. 3 in a MAPPER setup;

FIG. 5 shows a band energy scheme of a semiconductor field emission array as shown in FIG. 3;

FIG. 6 shows the current on a logarithmic scale flowing from a tip of a semiconductor field emission array as shown in FIG. 3, as function of the inverse voltage across the tip.

FIG. 7 shows an embodiment of the semiconductor field emission array made of a very thin layer.

FIGS. 8a, 8b, 9a, and 9b show several energy band curves for an interface layer between a semiconductor layer and a supporting layer;

FIGS. 10a and 10b show holes in the semiconductor layer to prevent cross talk between adjacent electron sources.

FIG. 11 shows an embodiment of the semiconductor field emission array with an additional fluorescent layer.

FIG. 12 shows an embodiment of the semiconductor field emission array with an additional fluorescent layer and an additional transparent layer.

### DESCRIPTION OF EMBODIMENTS

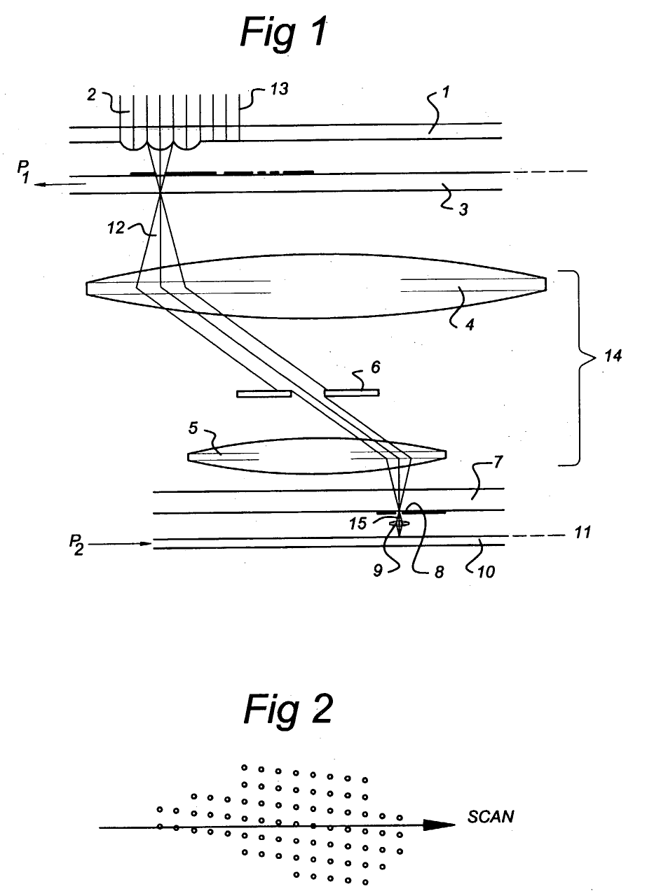

FIGS. 1 and 2 have been explained above.

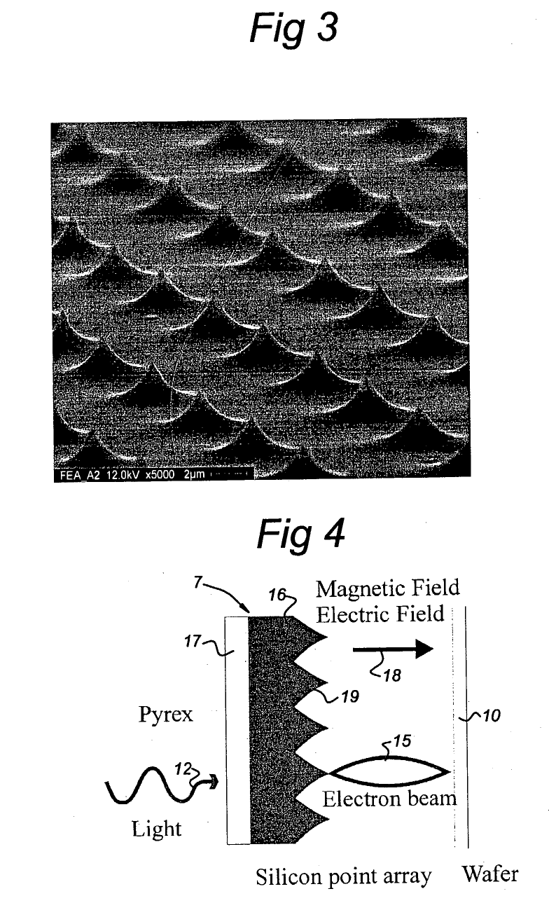

In accordance with the invention the converter plate 7 comprises a semiconductor field emission array as shown in FIG. 3. FIG. 3 shows a plurality of tips on a p-doped silicon substrate. The image has been made by means of a Scanning Electron Microscope (SEM). The silicon wafer was sized 5 mm×5 mm. 81×81 tips were etched on the wafer surface. The tips shown were spaced about 8 μm whereas their height was about 4 μm. Of course, these figures are only examples. To further enhance the resolution on the wafer 10 to be processed, it is envisaged that the tips may be located closer to one another than 8 μm.

The front surface from the tips, from which the electrons leave the silicon, have a diameter of preferably less than 100 nm, even more preferably less than 50 nm.

FIG. 3 shows conically shaped tips. However, the invention is not limited to such a shape. The tips may have a rectangle or other shaped cross section, or are shaped like a sphere.

A structure a shown in FIG. 3 has been disclosed by Schroder e. a. referred to above. It has the following characteristics:

field emission is limited by the availability of electrons in the operating regime

electrons are excited from the valence band in the conduction band by photons from the impinging beamlets 12

tunnel probability approaches 1

due to field penetration in the tips the sources are less sensitive for pollution than metallic emitters.

FIG. 4 shows the operation of the semiconductor field emission array 7 in more detail. The array 7 comprises a supporting substrate 17, e.g., made of Pyrex, but any other suitable material can be used. The supporting substrate must be made from a material that has a very low absorption factor for the wavelength of the light beamlets 12. For instance, when UV light is used the material may be quartz. On top of the supporting substrate 17 a semiconductor point array layer 16 is provided, preferably made of p-doped silicon. However, by applying another semiconductor material the band gap between the valence band and the conduction band may be tuned to the wavelength of the light beamlets 12 used.

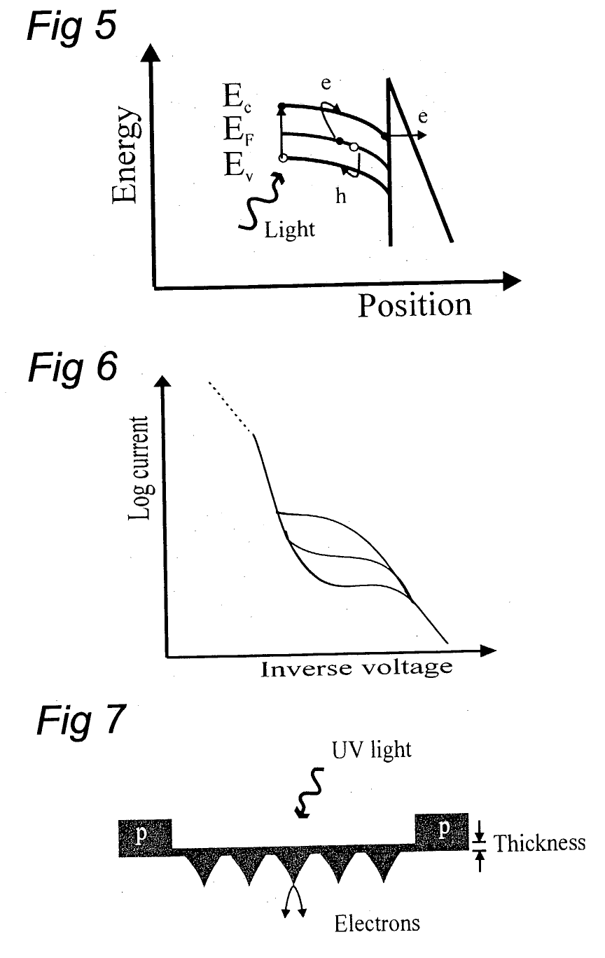

The structure shown in FIG. 4 is used in the transmissive mode, i.e., light beamlet 12 impinges on the supporting substrate 17. The material used for the supporting substrate must be transparent to the wavelength of the light used. The photons from the light travel through the supporting substrate 17 and reach the semiconductor layer 16 where they will generate electrons, as will be further explained with reference to FIG. 5 below.

The electrons leave the silicon layer 16 substantially at the front surface of the tips 19.

An external (constant) electrical and magnetic field 18 accelerate the electrons and focus them on the wafer 10 to be processed. The electrical and magnetic fields are preferably directed in parallel from the silicon layer 16 towards the wafer 10 to be processed.

Although FIG. 4 shows light beamlets 12 impinging on the converter plate 7 on the rear side the invention is not limited to such an embodiment. Instead, the light 12 may impinge on the converter plate 7 from another direction.

Moreover, the generated electrons may be accelerated and focused by other means, as is known to persons skilled in the art.

FIG. 5 shows the energy bands of the silicon layer 16. The vertical axis shows the energy and the horizontal axis shows the position within the silicon layer 16. The most relevant energy bands are shown:

Ec=energy of the conduction band

Ev=energy of the valence band

Ef=energy of the Fermi level, which is between Ec and Ev.

The vertical line at the right hand side of the energy bands corresponds to the boundary of the tip 19 at the interface with the external vacuum. The most right beveled line corresponds to the external electrical field. Its inclination is determined by the strength of the external electrical field.

Since the conversion material is made from a semiconductor there are few electrons in the conduction band Ec. By illuminating the semiconductor with light a photoelectric effect occurs within the semiconductor material. A photon excites an electron from the valence band Ev to the conduction band Ec.

FIG. 5 shows that the energy bands are curved at the outside surface of the tips 19. This is caused by the external electrical field that penetrates the semiconductor material. The curved energy bands cause electrons, indicated with “e”, in the conduction band Ec to be accelerated towards the interface of tips 19 and the external vacuum.

During their acceleration within the semiconductor material, these electrons may excite further electrons from the valence band to the conduction band. On the other hand, some of the electrons will fall back to the valence band. Including this latter effect, still an efficiency of 1 for the conversion of electrons per photon may be obtained. At the same time, holes, indicated with “h”, left behind in the valence band By are accelerated in the opposite direction. When a high external electric field is applied there is a high change for electrons in the conduction band Ec to tunnel from the material towards the external vacuum.

The electrical current thus generated by the impinging photons is mainly determined by the availability of electrons in the conduction band EO and less by the external electrical field strength.

FIG. 6 shows the electrical current generated by the impinging photons on a logarithmic scale as a function of the voltage across the tips 19. The voltage is shown on an inverse scale, i. e., the voltage increases going from right to left.

FIG. 6 shows that, starting at the right hand side of the curve, when the voltage increases above a certain first threshold the log current starts to deviate from a straight line and smoothes to a more or less constant level. When the voltage increases further above a second threshold the log current increases sharply and returns to the original straight line.

In the region where the log current is smoothed the actual log current strength depends on, for instance, temperature and the amount of light in the beamlets 12. Therefore, in this region the impinging light can control the current strength. This effect is discussed in detail in the article of Schroder e. a. referred to above.

Preferably, light is used having a wavelength of 400 nm or less, e. g., 193 nm.

The pressure within the system shown in FIG. 1 may be higher than 10-7 mbar. Even with such a relatively high pressure, the converter element 7 is stable.

In FIG. 7 an embodiment of the semiconductor emission array 7 is shown with a thickness of typically 100 nm or less. Typically the thickness of the semiconductor emission array 7 may be 20-30 μm, however, by making the semiconductor layer 7 so thin, electrons generated at the side that is illuminated by the beamlets 12 have either themselves a higher change of reaching the tips 19 or generate secondary electrons by collisions with semiconductor atoms that may reach the tips 19. Therefore, the embodiment of FIG. 7 improves the efficiency of the converter element 7.

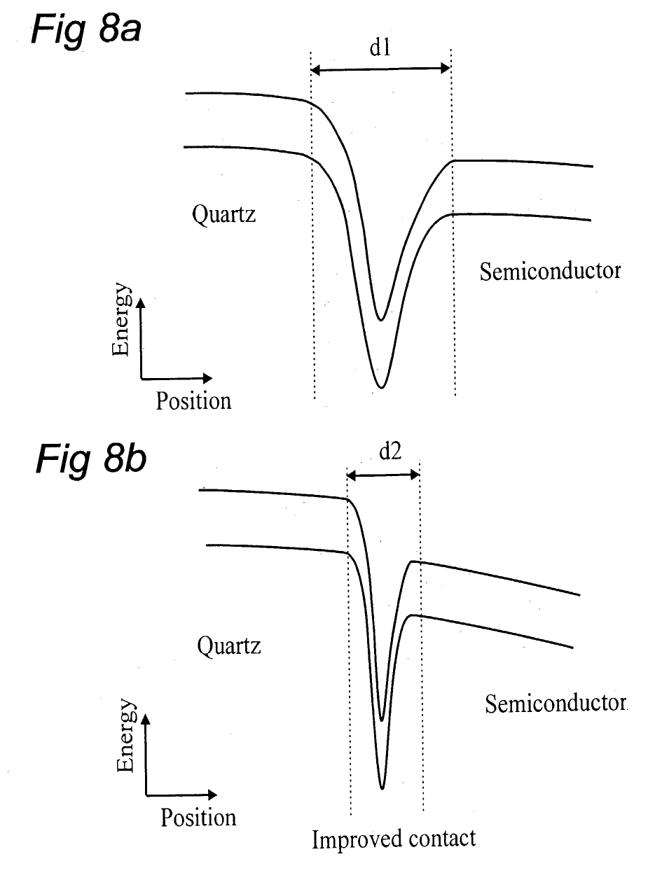

FIG. 8a shows how the valence bands (lower curve) and conduction bands (upper curve) within a quartz substrate 17 and the semiconductor layer 16 will be as a function of location when these two layers are connected to one another. As shown, in an interface layer with a thickness of d1 the band pattern shows a pit. The pit causes electrons generated in this interface layer to have great difficulty in flowing to the tip side of the semiconductor layer 16, thus decreasing the efficiency of conversion.

The efficiency can be improved by depositing the quartz layer 17 on the semiconductor layer 16 very slowly in a controlled way. Then, the width of the interface layer will be decreased to d2 (d2<d1). Such a smaller width d2 results in less electrons being trapped in the interface layer and, thus, more electrons being capable of reaching the tips 19 of the semiconductor layer 16.

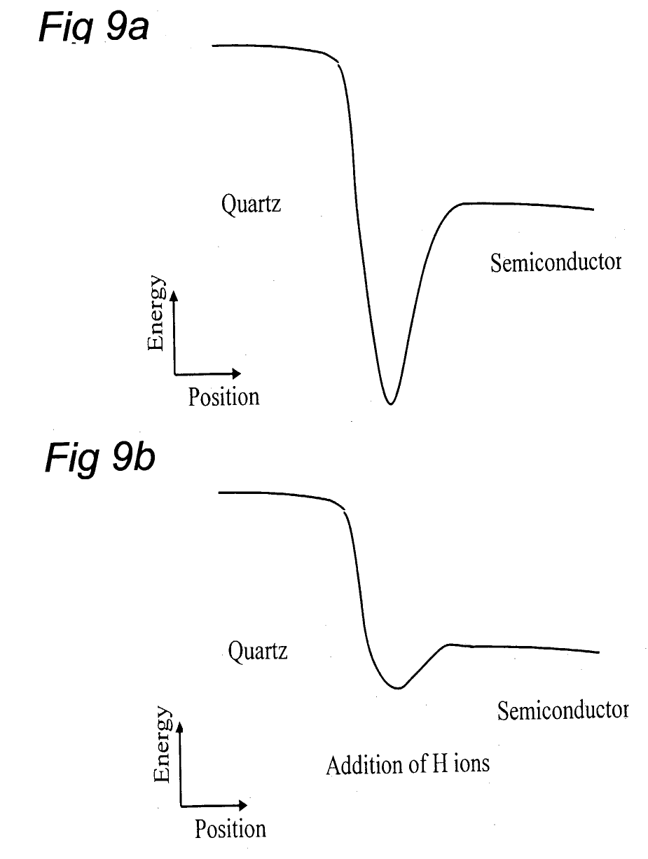

It is also possible to lower the depth of the pit in the interface layer by diffusing, e. g., H+ ions through the quartz layer 17 into the interface layer, as shown in FIG. 9b.

FIG. 9a shows the pit in the interface layer without such H+ ions being added. FIGS. 9a and 9b (as well as FIGS. 8a and 8b) are not on scale but they give a fair impression of the effects concerned. The H+ ions compensate the electron configuration in the interface layer. Instead of H+ ions other atoms/ions may be used to provide this effect.

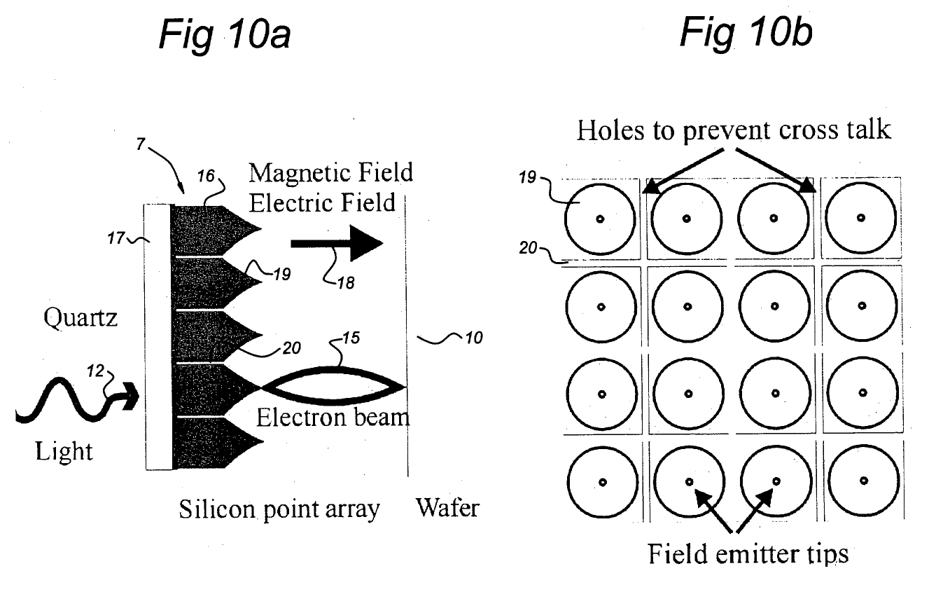

In the Mapper system of FIG. 1, it is important that each light beamlet 12 triggers only one electron beam via one tip 19 and does not trigger any of its adjacent tips 19. This may be facilitated by removing material in the semiconductor layer 16 behind the tips 19. This may be done by making rectangular or other holes 20 in the semiconductor layer 16 surrounding the tips 19 as shown in FIGS. 10a and 10b. FIG. 10a shows a cross section through such a semiconductor layer 16 whereas FIG. 10b shows a top view.

The conversion efficiency of all embodiments mentioned above can be further improved by adding an additional fluorescent layer. Many materials that would be suitable as converter material show a high absorption factor for light of small wavelengths i.e. smaller than 400 nm e.g. 193 nm.

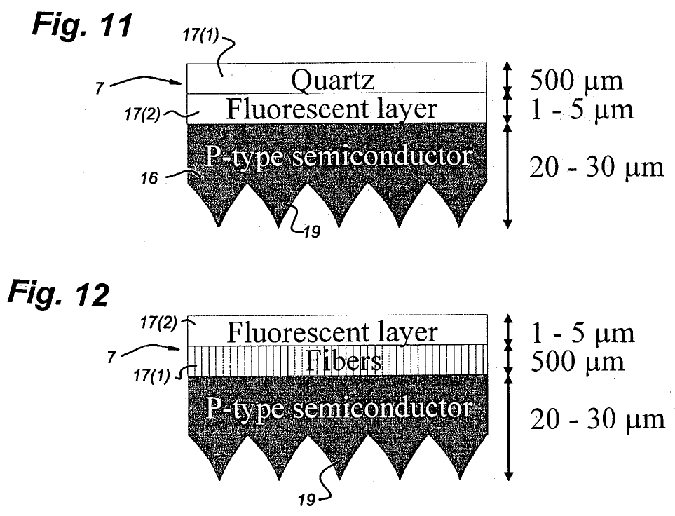

In a first embodiment, as shown in FIG. 11, the substrate 17 of the converter plate 7 comprises two sublayers 17 (1), 17 (2). Sublayer 17 (1) is made of quartz and suitable to be transmissive for light with wavelengths in the UV range. Preferably, it is transparent to wavelengths of 400 nm or less, e.g., 248 nm. For still lower B's CaF2 or BaF2 lenses may be used instead of quartz. The sublayer 17 (1) is indicated to be 500 μm thick, however, any other suitable thickness may be applied.

The sublayer 17 (2) is made of a suitable fluorescent material selected to receive light in the W range and to convert the received UV photons into photons with larger wavelengths and thus less energy, for instance in the Infra Red range. A portion of these photons with larger wavelength will travel to the photocathode array 16 and will be less absorbed by the photocathode array material than the UV photons of the impinging light beamlets 12. Still, they will have enough energy to generate electrons within the photocathode array 16 by the photoelectric effect, as explained above. The photocathode array 16 may be made of a semiconductor material provided with tips 19, as shown in FIGS. 11 and 12. However, any other suitable material may be applied.

For instance, when the semiconductor material is silicon electrons may be generated by photons having a wavelength of up to 1.1 μm, whereas for germanium photons with a wavelength of up to 1.6 μm may be used (cf. Schroder, referred to above).

Thus, by applying a fluorescent sublayer 17 (2), which converts photons having short wavelengths in the UV range to photons having larger wavelengths the efficiency of the converter element 7, can be improved in two ways:

1. The photons with larger wavelength will be absorbed less by the photocathode array 16 than the original photons

2. The fluorescent material may be selected such that the generated photons with larger wavelength are in a range for an optimum photoelectric effect in the photo cathode array 16. For instance, for p-doped (111) silicon, 10 Ω. cm, an optimum range for those latter photons may be 0.5 to 1.0 μm (cf. Schroder, FIG. 17).

The fluorescent layer 17 (2) is indicated to have a thickness of 1-5 μm, however, if desired another thickness may be chosen. The thickness of the photocathode array 16 may be 20-30 μm, however, again this is just an example.

FIG. 12 shows an alternative embodiment in which the fluorescent sublayer 17 (2) and the transparent sublayer 17 (1) have been interchanged. The sublayer 17 (1) may be made of quartz, however, when the fluorescent sublayer 17 (2) produces photons with wavelengths larger than those of UV light other materials can be used.

In FIG. 12 vertical lines are drawn in sublayer 17 (1). These are to indicate that sublayer 17 (1) may comprise glass fibers to avoid scattering of light produced by fluorescent layer 17 (2).

In order to prevent spherical aberrations from adversely affecting the imaging from electron sources on the object 10, a diaphragm may be located behind each of the tips 19. These diaphragms decrease the aperture angle from the electron beams at the tips 19.

It is observed that the invention has been illustrated above with reference to its use in a multiple light beam lithography system as shown in FIG. 1. However, the invention can also be used in other types of lithography systems. For instance, instead of modulating the beamlets 12 with mask 3, they may be modulated by modulating sources that produce them. Moreover, as a further alternative, the invention may be used in any single beam or multi-beam electron lithography system, e.g., an “electron beam direct write” system. Electron sources used in such systems should have the following features:

very small source dimensions

high current per electron source, i.e., high brightness; high stability over time

large homogeneity between individual electron sources when a plurality of sources is used at the same time

a large bandwidth, i.e., the sources must be capable of being switched on and off with a high frequency.

All these requirements can be met by the semiconductor field emission array proposed here.

In other types of lithography systems (not shown), then, the semiconductor field emission array 7 may, e. g., be illuminated by a single light beam 13. Then, no mask 3 and demagnifier 14 are used. By illuminating the entire field emission array 7, all tips 19 will generate electrons simultaneously. By means of alignment deflectors, each electron beam can be accurately positioned through a small blanking aperture on the object 10 to be processed. Blanking electrodes may be used to turn the individual electron beams on and off at the vicinity of the object 10 in order to write a desired pattern on the object surface. An example of such a multi-beam direct write electron beam lithography system in which the semiconductor field emission array 7 could be used is described in: Dot matrix electron beam lithography, T. H. Newman, R. F. W. Pease and W. DeVore, J. Vac Sci. Technol. B1, 999 (1983).

We claim:

1. Use of an electron source in a lithography system for producing a plurality of electron beams directed towards an object to be processed, said electron source comprising a plurality of field emitters, characterized in that said electron source comprises a semiconductor layer with a plurality of tips, said use including the steps of:
producing a plurality of light spots on said electron source, producing one light spot on one field emitter;
exciting electrons to a conduction band (E_{c}) by light from a light spot within said field emitter by a photo-electric effect;
accelerating said electrons in said conduction band (E_{c}) towards said tips and tunnelling them outside tips in order to generate electrons for said plurality of electron beams,
causing tips to generate electrons for said electron beam having a spot smaller than 100 nm on an object to be processed, each spot of light triggering an electron beam from one tip.

2. Use according to claim 1, wherein the lithography system comprises at least one microlens to produce one light beamlet directed to a mask located in a mask location and an optical demagnifier for demagnifying said light beamlet by a predetermined factor and focusing the beamlet on said electron source.

3. Use according to claim 1 or 2, wherein said at least one light spot and said at least one spot of said electron beam are aligned.

4. Use according to claim 1, 2 or 3, wherein said at least one light spot and said at least one tip are aligned.

5. Use according to claim 4, wherein said electron source comprises a plurality of tips in one plane.

6. Use according to claim 5, wherein a plurality of light spots are produced on the electron source, each light spot being aligned with each tip or electron beam spot.

7. Use according to any one of the preceding claims, wherein the electron source comprises a semiconductor layer with at least one tip.

8. Use according to claim 7, wherein said semiconductor layer comprises silicon.

9. Use according to claim 8, wherein said silicon is p-doped.

10. Use according to any of the preceding claims, wherein said at least one tip has a front surface with a diameter of 100 nm or less.

11. Use according to claim 11, wherein said diameter is 50 nm or less.

12. Use according to any of the preceding claims, wherein said semiconductor layer comprise a plurality of tips.

13. Use according to claim 12, wherein said plurality of tips have intermediate spaces of less than 8 μm.

14. Use according to claim 12 or 13, wherein said plurality of tips have heights of 8 μm or less.

15. Use according to any of the preceding claims, wherein said electron beam is generated by an electric field and focused by a magnetic field.

16. Use according to any of the preceding claims furthermore provided with a wavelength-converting step to convert the incoming light beams of a first wavelength into outgoing light beams of a second wavelength larger than said first wavelength.

17. Use according to claim 16, wherein said electron source is provided with a fluorescent layer on a light receiving side of said electron source.

18. A lithography system comprising an electron source for receiving light and for generating a plurality of electron beams directed towards an object to be processed, said electron source comprising a plurality of field emitters comprising a semiconductor layer with at least on tip, said lithography system further comprising means for generating a plurality of light spots on said electron source, the positions of light spots on the field emitters corresponding to positions of tips, and said field emitter being arranged to:
excite electrons to a conduction band (E_{c}) by light from a light spot within said field emitter by a photo-electric effect;
accelerate said electrons in said conduction band (E_{c}) towards tips and tunnel them outside tips in order to generate electrons for said plurality of electron beams,
said lithography system further comprising means for modifying the generated electron into said plurality electrons beam for producing a plurality of spots on an object to be processed smaller than 100 nm, each spot of light triggering an electron beam from one tip.

19. Lithography system according to claim 18, wherein said system comprises at least one microlens to produce one light beamlet directed to a mask located in a mask location and an optical demagnifier for demagnifying said light beamlet by a predetermined factor and focusing the beamlet on said electron source.

20. Lithography system of claims 18 or 19, wherein the means for generating at least one light spot is adapted for having the light spot triggering an electron beam from one tip.

21. Lithography system according to claim 18-20, wherein said at least one light spot and said at least one spot of said electron beam are aligned.

22. Lithography system according to claims 18-20, wherein said at least one light spot and said at least one tip are aligned.

23. Lithography system according to claims 21 or 22, wherein said electron source comprises a plurality of tips in one plane.

24. Lithography system according to claim 23, wherein a plurality of light spots are produced on the electron source, each light spot being aligned with each tip or electron beam spot.

25. Lithography system according to any one of the preceding claims 18-24, wherein the electron source comprises a semiconductor layer with at least one tip.

26. Lithography system according to claim 25, wherein said semiconductor layer comprises silicon.

27. Lithography system according to claim 26, wherein said semiconductor silicon is p-doped.

28. Lithography system according to any of the claims 18-27, wherein said at least one tip has a front surface with a diameter of 100 nm or less.

29. Lithography system according to claim 28, wherein said diameter is 50 nm or less.

30. Lithography system according to any of the claims 18-29, wherein said semiconductor layer comprises a plurality of tips.

31. Lithography system according to claim 30, wherein said plurality of tips have intermediate spaces of less than 8 μm.

32. Lithography system according to claim 28 or 31, wherein said plurality of tips have heights of 8 μm or less.

33. Lithography system according to any of the claims 18-32, wherein said electron beam is generated by a magnetic and an electric field.

34. Lithography system according to claim 19, wherein said system comprises a plurality of microlenses to produce a plurality of light beamlets.

35. Lithography system according to claim 34, wherein said system comprises between 10⁶ and 10⁸ microlenses.

36. Lithography system according to any of the claims 25-35, wherein said semiconductor layer has a thickness of less than 30 μm, preferably less than 100 nm.

37. Lithography system according to any of the claims 25-36, wherein said semiconductor layer is provided with at least one hole surrounding said at least one tips.

38. Lithography system according to any of the claims 18-37, furthermore provided with a fluorescent layer to convert said light beams having a first wavelength into light beams with a second wavelength larger than said first wavelength.

39. Lithography system according to claim 38, furthermore provided with a transparent layer between said semiconductor layer and said fluorescent layer.

40. Lithography system according to claim 39, wherein said transparent layer is made of quartz.

41. Lithography system according to claim 39, wherein said transparent layer comprises a plurality of optical fibres.

42. Lithography system according to claim 37, wherein said fluorescent layer is provided on a light-spots receiving side of said electron source.
